(19) United States
(12) Patent Application Publication
(10) Pub. No.: US 2012/0025215 A1
(43) Pub. Date: Feb. 2, 2012

(54) SEMICONDUCTOR PACKAGE WITH HEAT DISSIPATING STRUCTURE

(75) Inventors: CHIEN-MIN CHEN, Hsinchu (TW); YA-WEN LIN, Hukou Shiang (TW)

(73) Assignee: ADVANCED OPTOELECTRONIC TECHNOLOGY, INC., Hsinchu Hsien (TW)

(21) Appl. No.: 13/029,124

(22) Filed: Feb. 17, 2011

(30) Foreign Application Priority Data
Jul. 29, 2010 (CN) 201010238787.7

(51) Int. Cl. H01L 33/64; H01L 23/48; H01L 23/34

(52) U.S. Cl. 257/88; 257/690; 257/698; 257/E33.075; 257/E23.011; 257/E23.08

(57) ABSTRACT

A semiconductor package includes a substrate, a number of electrodes formed in the substrate, a heat dissipating member fixed on the substrate, and at least one semiconductor chip mounted on the heat dissipating member and electrically connected to the electrodes. The heat dissipating member defines a receiving through hole and includes a conducting portion formed at the bottom of the receiving through hole. The at least one semiconductor chip is mounted on the conducting portion. The conducting portion efficiently conducts the heat generated by the semiconductor chip to the heat dissipating member and improves the heat dissipating efficiency of the semiconductor package.

### BACKGROUND

1. Technical Field

The present disclosure relates to semiconductor packages, and more particularly to a light emitting element package having a heat dissipating structure.

2. Description of Related Art

Generally, a light emitting element package includes a substrate, a semiconductor chip, such as a light emitting diode (LED) chip, attached on the substrate and a heat dissipating member fixed on the substrate. The heat generated by the LED chip is conducted to the heat dissipating member through the substrate and is dissipated to an exterior environment through the heat dissipating member. However, because the thermal conductivity of the substrate is usually much less than the heat dissipating member, the heat dissipation efficiency of the light emitting element package is somehow compromised.

Therefore, it is desirable to provide a semiconductor package which can overcome the above-mentioned shortcomings.

### BRIEF DESCRIPTION OF THE FIGURE

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic top view of a semiconductor package according to one embodiment of the present disclosure.

FIG. 2 is a cross-sectional view of the semiconductor package taken along line II-II of FIG. 1.

FIG. 3 is a cross-sectional view of the semiconductor package taken along line III-III of FIG. 1.

### DETAILED DESCRIPTION

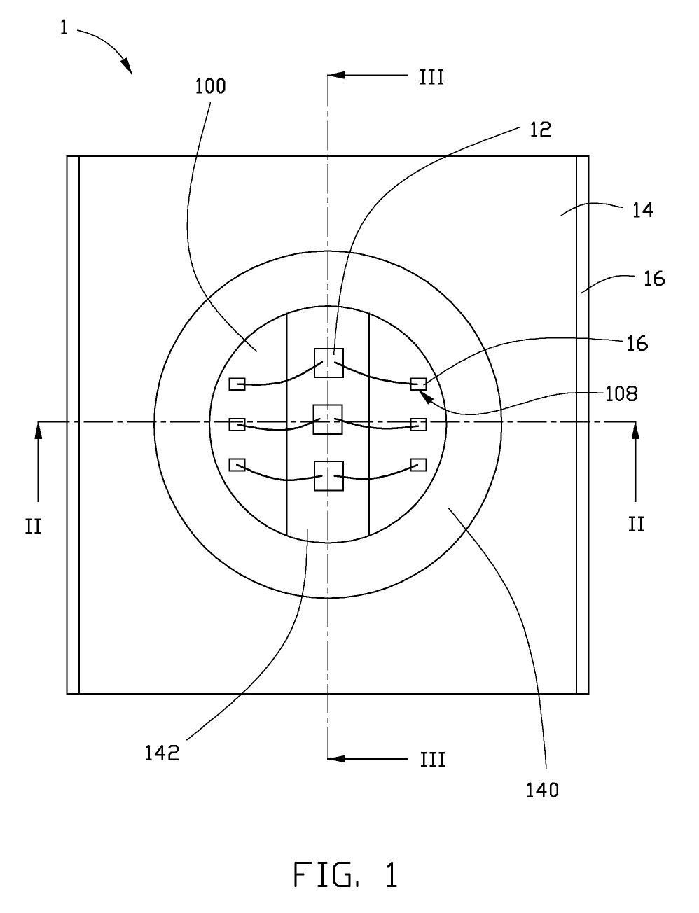

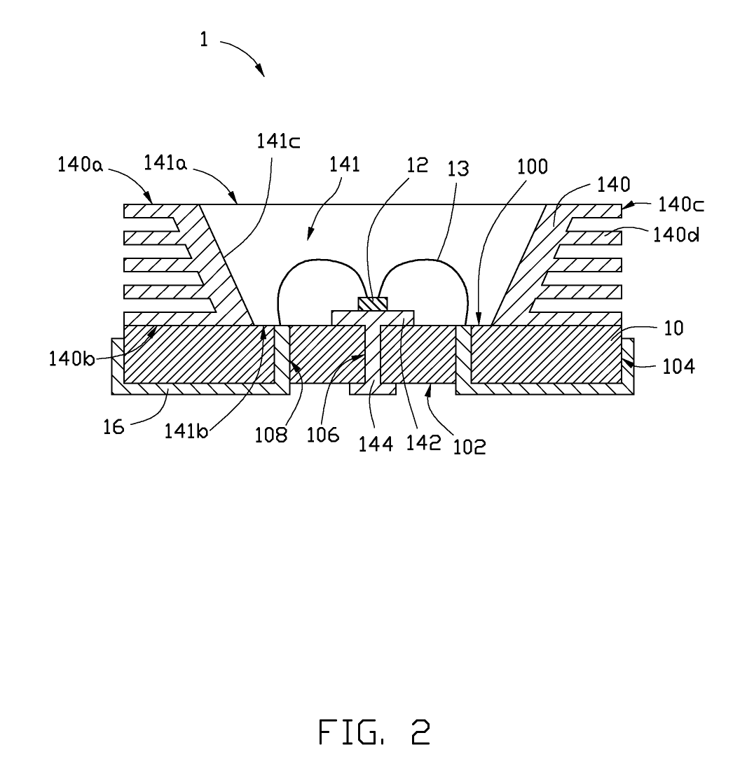

Referring to FIGS. 1 and 2, a semiconductor package 1 includes a substrate 10, at least one semiconductor chip attached on the substrate 10, a heat dissipating member 14 fixed on the substrate 10, and a number of electrodes 16 formed in the substrate 10. In this embodiment, the at least one semiconductor chip includes a number of LED chips 12.

The substrate 10 is made of electrically insulating material with a high thermal conductivity, such as beryllium oxide (BeO), carborundum (SiC), aluminum nitride (AlN), alumina (AlO), or high-temperature plastic. The substrate 10 includes an upper surface 100, a lower surface 102 parallel and opposite to the upper surface 100, and a side surface 104. The side surface 104 perpendicularly connects the peripheries of the upper and lower surfaces 100, 102. The substrate 10 defines a first through hole 106 perpendicularly extending from a center of the upper surface 100 to the lower surface 102. The substrate 10 also defines a number of second through holes 108 perpendicularly extending from the upper surface 100 to the lower surface 102. The second through holes 108 are arranged in two rows and correspondingly located at opposite sides of the first through hole 106. In this embodiment, the second through holes 108 in each side are arranged in a line and equidistantly spaced from each other.

Each electrode 16 penetrates the substrate 10 via one corresponding second through hole 108 and then extends transversely from the lower surface 102 to the adjacent side surface 104.

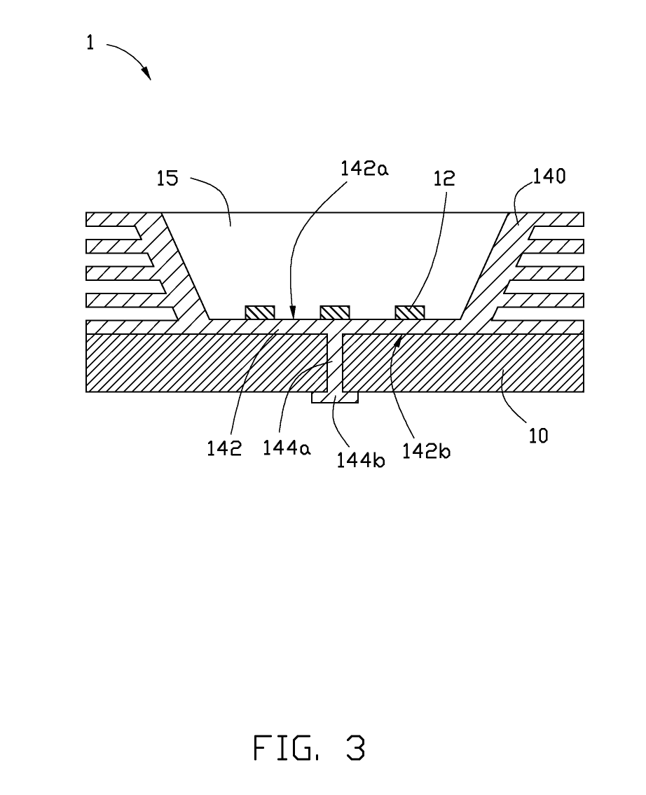

Referring to FIGS. 2 and 3, the heat dissipating member 14 is configured to dissipate the heat from the LED chips 12 to an exterior environment. In this embodiment, the heat dissipating member 14 is made of metal with high thermal conductivity and high reflectivity, such as copper, aluminum, iron, or an alloy thereof. The heat dissipating member 14 includes a dissipating portion 140, a conducting portion 142, and a fastening portion 144. The dissipating portion 140 includes a top surface 140a, a bottom surface 140b opposite to the top surface 140a, and a side wall 140c connecting an outer periphery of the top and bottom surfaces 140a, 140b. A fin set 140d including a plurality of fins is formed on the side wall 140c to increase the heat dissipating area of the dissipating portion 140. In this embodiment, each fin of the fin set 140d is extended in parallel with the top and bottom surfaces 100, 102. The bottom surface 140b of the dissipating portion 140 tightly engages with the upper surface 100 of the substrate 10 and occupies a quite large portion of the upper surface 100 (as best seen from FIG. 1).

The dissipating portion 140 defines a receiving through hole 141 extending from a center of the top surface 140a to the bottom surface 140b. The receiving through hole 141 defines an upper opening 141a, a lower opening 141b, and an inner wall 141c connecting the upper and lower openings 141a, 141c. In this embodiment, the upper opening 141a is wider than the lower opening 141b and the inner wall 141c is a downwardly inwardly inclined surface.

The conducting portion 142 is an elongated metal sheet and includes a first surface (i.e., top surface) 142a and a second surface (i.e., bottom surface) 142b opposite to the first surface 142a. In this embodiment, the conducting portion 142 extends along a diametrical direction of the lower opening 141b. Two opposite ends of the conducting portion 142 are correspondingly connected to the periphery of the lower opening 141b. In this embodiment, the second surface 142b tightly engages with the upper surface 100 of the substrate 10 and is coplanar with the bottom surface 140b of the dissipating portion 140.

The fastening portion 144 is configured in inverted-“T” shape and includes a connecting pole 144a and a stopper 144b. One end of the connecting pole 144a connects a center of the conducting portion 142 at the second surface 142b. The stopper 144b is formed on the other end of the connecting pole 144a far from the second surface 142b.

In assembly, the dissipating portion 140 is attached to the substrate 10 with the bottom surface 140b engaging with the upper surface 100. The connecting pole 144a is received in the first through hole 106 and the stopper 144b abuts against the lower surface 102 of the substrate 10 to prevent the heat dissipating member 14 from moving relative to the substrate 10. The electrodes 16 penetrate the substrate 10 via the second through holes 108 and are exposed upwardly through the upper surface 100 of the substrate 10 at opposite sides of the conducting portion 142. In this embodiment, the dissipating portion 140, the conducting portion 142, the fastening portion 144, and the substrate 10 are formed together through low temperature co-fired process. The dissipating portion 140, the conducting portion 142 and the fastening portion 144 are integrally formed as a single piece.

The LED chips 12 are mounted on the first surface 142a of the conducting portion 142. Each LED chip 12 is electrically connected to one pair of electrodes 16 exposed at opposite sides of the conducting portion 142 via two golden wires 13. Heat generated by the LED chip 12 is conducted to the dissipating portion 140 through the conducting portion 142 and is dissipated through the fin set 140d of the dissipating portion 140. Because the conducting portion 142 and the dissipating portion 140 are integrally made of metal with high thermal conductivity, the efficiency of the heat dissipating efficiency of the semiconductor package 1 can be greatly improved.

It is understood that an encapsulation material 15 with high light perviousness can be filled in the receiving through hole 141 to modulate the characteristics of light generated by the LED chips 12.

While various embodiments have been described, it is to be understood that the invention is not limited thereto. To the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A semiconductor package comprising:
a substrate;
a plurality of electrodes formed in the substrate;
at least one semiconductor chip electrically connected to the electrodes; and
a heat dissipating member fixed on the substrate, wherein the heat dissipating member defines a receiving through hole and comprises a conducting portion formed at the bottom of the receiving through hole and covering a part of the receiving through hole, and the at least one semiconductor chip is received in the receiving through hole and mounted on the conducting portion, heat generated by the at least one semiconductor chip being absorbed by the conducting portion to be dissipated by the heat dissipating member.

2. The semiconductor package as claimed in claim 1, wherein the heat dissipating member further comprises a top surface, a bottom surface, and a side wall connecting the top surface and the bottom surface, the receiving through hole converges from the top surface to the bottom surface, and the conducting portion extends along a diametrical direction of a lower opening of the receiving through hole and joins the bottom surface of the heat dissipating member.

3. The semiconductor package as claimed in claim 2, further comprising a fin set extending outwardly from the side wall, the fin set comprising a plurality of fins parallel to the top and bottom surfaces.

4. The semiconductor package as claimed in claim 2, wherein an inner wall of the heat dissipating member surrounding the receiving through hole is an inclined surface.

5. The semiconductor package as claimed in claim 1, wherein the conducting portion comprises a first surface and a second surface opposite to the first surface, the second surface is substantially coplanar with the bottom surface, and the semiconductor chip is mounted on the first surface.

6. The semiconductor package as claimed in claim 1, wherein the heat dissipating member further comprises an inverted-T shaped fastening portion for fixing the conducting portion tightly to the substrate, and the conducting portion is integral to the fastening portion as a single piece.

7. The semiconductor package as claimed in claim 6, wherein the substrate comprises an upper surface, a lower surface opposite to the upper surface, the substrate defines a first through hole perpendicularly extending from the upper surface to the lower surface.

8. The semiconductor package as claimed in claim 7, wherein the fastening portion comprises a connecting pole perpendicularly connecting to the conducting portion at one end and a stopper formed on the other end of the connecting pole.

9. The semiconductor package as claimed in claim 8, wherein the connecting pole is received in the first through hole, and the stopper abuts against the lower surface of the substrate.

10. The semiconductor package as claimed in claim 7, wherein the substrate defines a plurality of second through holes perpendicularly extending from the upper surface to the lower surface, the second through holes are arranged in two rows and correspondingly located at opposite sides of the first through hole.

11. The semiconductor package as claimed in claim 10, wherein each electrode penetrates the substrate via one corresponding second through hole and then extends transversely from the lower surface to the side surface.

12. The semiconductor package as claimed in claim 1, wherein the substrate is made of materials selected from the group consisting of beryllium oxide, carborundum, aluminum nitride, alumina, and high-temperature plastic.

13. The semiconductor package as claimed in claim 1, wherein the at least one semiconductor chip comprises a plurality of LED chips.

14. The semiconductor package as claimed in claim 13, wherein the LED chips are arranged in a line on the conducting portion.

15. The semiconductor package as claimed in claim 14, wherein the plurality of electrodes is arranged in two lines respectively at two opposite sides of the conducting portion.

16. The semiconductor package as claimed in claim 15, wherein each LED chip is electrically connected with two of the electrodes at the two opposite sides of the conducting portion via two golden wires.
